(19) United States
(12) Patent Application Publication
(10) Pub. No.: US 2009/0178700 A1
(43) Pub. Date: Jul. 16, 2009

(54) THERMOELECTRIC FIGURE OF MERIT ENHANCEMENT BY MODIFICATION OF THE ELECTRONIC DENSITY OF STATES

(75) Inventors: Joseph P. Heremans, Upper Arlington, OH (US); Vladimir Jovovic, Columbus, OH (US)

Correspondence Address: KNOBBE MARTENS OLSON & BEAR LLP, 2040 MAIN STREET, FOURTEENTH FLOOR, IRVINE, CA, 92614, US

(73) Assignee: The Ohio State University Research Foundation, Columbus, OH (US)

(21) Appl. No.: 12/353,153

(22) Filed: Jan. 13, 2009

Related U.S. Application Data
(60) Provisional application No. 61/020,986, filed on Jan. 14, 2008.
(60) Provisional application No. 61/021,391, filed on Jan. 16, 2008.

(51) Int. Cl. H01L 35/34; H01B 1/02

(52) U.S. Cl. 136/201; 252/512

(57) ABSTRACT

A thermoelectric material and a method of fabricating a thermoelectric material are provided. The thermoelectric material includes a doped compound of at least one Group IV element and at least one Group VI element. The compound is doped with at least one dopant selected from the group consisting of: at least one Group Ia element, at least one Group IIb element, at least one Group IIIa element, at least one Group IIIb element, at least one lanthanide element, and chromium. The at least one Group IV element is on a first sublattice of sites and the at least one Group VI element is on a second sublattice of sites, and the at least one Group IV element includes at least 95% of the first sublattice sites. The compound has a peak thermoelectric figure of merit ZT value greater than 0.7 at temperatures greater than 500 K.

This application claims the benefit of U.S. Provisional Application No. 61/020,986 filed Jan. 14, 2008, which is incorporated herein in its entirety by reference.

### BACKGROUND OF THE INVENTION

1. Field of the Invention

The present application relates generally to thermoelectric materials, and more specifically to thermoelectric devices comprising a semiconductor compound.

2. Description of the Related Art

Thermoelectric (TE) energy conversion is an all-solid-state technology used in heat pumps and electrical power generators. In essence, TE coolers and generators are heat engines thermodynamically similar to conventional vapor power generator or heat pump systems, but they use electrons as the working fluid instead of physical gases or liquids. Thus, TE coolers and generators have no moving fluids or moving parts and have the inherent advantages of reliability, silent and vibration-free operation, a very high power density, and the ability to maintain their efficiency in small-scale applications where only a moderate amount of power is needed. In addition, TE power generators directly convert temperature gradients and heat into electrical voltages and power, without the additional need for an electromechanical generator.

All of these properties make them particularly suited for recovering electrical power from otherwise wasted heat, for instance in automotive exhaust systems or solar energy converters. These advantages are partially offset by the relatively low efficiency of commercially available material, limiting the use of the technology to niche applications for the past half century. Recent efforts have focused on nanostructured materials to enhance the TE efficiency. Further examples of TE power systems are disclosed in U.S. Pat. Nos. 6,539,725, 7,231,772, 6,959,555, 6,625,990, and 7,273,981, which are incorporated herein in their entirety by reference.

The efficiency of thermoelectric generators is limited to a fraction of their Carnot efficiency (η_{c}=ΔT/T_{H}), determined by the dimensionless thermoelectric material figure of merit (1), ZT:

$$ZT = T \frac{{S}^{2} σ}{κ} \qquad ( 1 )$$

where S is the thermoelectric power or Seebeck coefficient of the TE material, σ and κ are the electrical and thermal conductivities, respectively, and T is the absolute temperature. For the past four decades, ZT of commercial material has been limited to about 1 in all temperature ranges (G. J. Snyder, E. S. Toberer, Nat. Mater., Vol. 7, pp. 105 (2008)).

The lead chalcogenides, and in particular PbTe, are prime materials for thermoelectric applications above about 200° C. (C. Wood, Rep. Prog. Phys., Vol. 51, pp. 459-539 (1988)). Dopants of indium, gallium, thallium, and cadmium introduced in PbTe form impurity levels (V. I. Kaidanov, Yu. I. Ravich, Sov. Phys. Usp., Vol. 28, pp. 31 (1985)) that are known to pin the Fermi energy at the impurity level itself. The energy level associated with indium impurities are about 70 meV (Kaidanov et al.; S. A. Nemov, Yu. I. Ravich, A. V. Berezin, V. E. Gasumyants, M. K. Zhitinskaya, V. I. Proshin, Semicond., Vol. 27 pp. 165 (1993)) inside the conduction band, as measured from the bottom of conduction band in PbTe (V. G. Golubev, N. I. Grecho, S. N. Lykov, E. P. Sabo, I. A. Chernik, Sov. Phys. Semicond., Vol. 11, pp. 1001 (1977); V. I. Kaidanov, R. B. Mel'nik, I. A. Chernik, Sov. Phys. Semicond. 7 759 (1973)). Therefore, chemical doping of these alloys can increase the Fermi energy beyond 70 meV only if the dopant concentration exceeds that of indium.

A study by Nemov et al. performed on Pb_{0.78}Sn_{0.22}Te with less than 3% indium showed a half-filled In—Te band and a Fermi level, E_{F}, stabilized at the impurity level positioned below the bottom of the conduction band edge. At indium concentrations above 5%, E_{F} would be positioned within k_{B}T of the impurity level, where k_{B} is Boltzmann's constant and T is the temperature. By measuring the temperature dependence of the Hall coefficient and the resistivity ρ, Nemov et al. determined the energy derivative of density of states, dg(E)/dE, and found that the gap between the impurity states and the conduction band disappears while dg(E)/dE becomes negative. This result implies that the energy band of the host semiconductor, here PbTe, hybridizes with the energy levels of the impurity and in this way, the impurity may form a resonant state in the band of the host semiconductor.

The existence of such a resonant state in the vicinity of the Fermi level results in a strong distortion of the density of states (DOS). The density of states' energy dependence, g(E), develops sharp, delta-shaped features which, following the theory of Mahan and Sofo (G. D. Mahan and J. O. Sofo, Proc. Natl. Acad Sci. USA, Vol. 93, pp. 7436 (1996)), can improve the thermoelectric figure of merit, ZT. This result can be expressed using the Mott relation:

$$\begin{matrix}S = \frac{{π}^{2}}{3} \frac{{k}_{B}}{q} {k}_{B} T {\{ \frac{d [ ln ( σ ( E ) ) ]}{d E} \}}_{E = {E}_{F}} \\ = \frac{{π}^{2}}{3} \frac{{k}_{B}}{q} {k}_{B} T {\{ \frac{1}{n} \frac{d n ( E )}{d E} + \frac{1}{μ} \frac{d μ ( E )}{d E} \}}_{E = {E}_{F}}\end{matrix} \qquad ( 2 )$$

which predicts that a strongly energy-dependent density of states, resulting in a strong dn/dE term in equation (2), should provide a higher value of the Seebeck coefficient S(n) at a given carrier concentration n than that of a simple parabolic or non-parabolic band. The dependence of the Seebeck coefficient S on the carrier concentration n is called the Pisarenko relation. (see, e.g., F. Ioffe, Physics of Semiconductors (Academic Press, New York, 1960)).

### SUMMARY OF THE INVENTION

In certain embodiments, a thermoelectric material is provided. The thermoelectric material comprises a doped compound of at least one Group IV element and at least one Group VI element. The compound is doped with at least one dopant selected from the group consisting of: at least one Group IIa element, at least one Group IIb element, at least one Group IIIa element, at least one Group IIIb element, at least one lanthanide element, and chromium. The at least one Group IV element is on a first sublattice of sites and the at least one Group VI element is on a second sublattice of sites, and the at least one Group IV element comprises at least 95% of the first sublattice sites. The compound has a peak thermoelectric figure of merit ZT value greater than 0.7 at temperatures greater than 500 K.

In certain embodiments, a thermoelectric material is provided. The thermoelectric material comprises a doped Group IV-Group VI semiconductor compound. The compound is doped with at least one dopant such that the compound has a density of electron states as a function of energy n(E) having an energy derivative dn(E)/dE with one or more maxima, and such that the Fermi level of the compound is located within kT of a maximum of the one or more maxima.

In certain embodiments, a method of fabricating a thermoelectric material is provided, The method comprising providing at least one Group IV element, at least one Group VI element, and at least one dopant in predetermined stoichiometric amounts. The at least one dopant is selected from the group consisting of: at least one Group IIa element, at least one Group IIb element, at least one Group IIIa element, at least one Group IIIb element, at least one lanthanide element, and chromium. The method further comprises combining the at least one Group IV element, the at least one Group VI element, and the at least one dopant together. The method further comprises treating the combination of the at least one Group IV element, the at least one Group VI element, and the at least one dopant with a predetermined temporal temperature profile. The combination of the at least one Group IV element, the at least one Group VI element, and the at least one dopant form a compound with the at least one Group IV element on a first sublattice of sites and the at least one Group VI element is on a second sublattice of sites. The at least one Group IV element comprises at least 95% of the first sublattice sites. The compound has a peak thermoelectric figure of merit ZT value greater than 0.7 at temperatures greater than 500 K.

### BRIEF DESCRIPTION OF THE DRAWINGS

FIG. 1 is a plot of the temperature dependence of the electrical resistivity of two sample thermoelectric materials compatible with certain embodiments described herein.

FIG. 2 is a plot of the temperature dependence of the Seebeck coefficients of the samples of FIG. 1.

FIG. 3 is a plot of the temperature dependence of the calculated figure of merit ZT from the data of FIGS. 1 and 2.

FIG. 4 is a plot of the temperature dependence of the thermal conductivity of the sample with 2 atomic % thallium.

FIG. 5 is a plot of temperature dependence of the low-field Hall coefficient (top frame), the Hall mobility (dots, bottom frame, left ordinate), and the Nernst coefficient (+ symbols, bottom frame, right ordinate) of the Tl_{0.02}Pb_{0.98}Te sample in FIG. 8. The open and closed symbols represent data taken in two different measurement systems.

FIG. 6 is a plot of the Seebeck coefficient versus carrier density, with the value for a sample compatible with certain embodiments described herein at 300 K shown as the circle datapoint and the Pisarenko curve valid for conventionally doped PbTe shown as the solid curve.

FIG. 7 includes plots of the temperature dependence of the (A) resistivity, (B) Seebeck coefficient, and (C) thermal conductivity of a representative sample of Tl_{0.02}Pb_{0.98}Te (squares) and of Tl_{0.01}Pb_{0.99}Te (circles). The open and closed symbols represent data taken in two different measurement systems.

FIG. 8 includes (A) a schematic representation of the density of electron states of the valence band of pure PbTe (dashed line) contrasted to that of Tl—PbTe in which a Tl-related level increases the density of states. The figure of merit ZT is optimized when the Fermi energy EF of the holes in the band falls in the energy range ER of the distortion; (B) a plot of ZT values for Tl_{0.02}Pb_{0.98}Te (squares) and Tl_{0.01}Pb_{0.99}Te (circles) compared to that of a reference sample of Na—PbTe (diamonds).

FIG. 9 is a plot of the temperature dependence of the Fermi energy (+ symbols, right ordinate, the zero referring to the top of the valence band) and of the density of states effective mass (dots, left ordinate) of Tl_{0.02}Pb_{0.98}Te compared to that of Na—PbTe (dashed line).

### DETAILED DESCRIPTION

Using Equation 2, measuring the Seebeck coefficient and the carrier density of the semiconductor doped with an impurity that may form a resonant state, and comparing that measurement to the Pisarenko relation valid for the parent semiconductor, constitutes a straightforward test for detecting resonance (Joseph P. Heremans, Vladimir Jovovic, Eric S. Toberer, Ali Saramat, Ken Kurosaki, Anek Charoenphakdee, Shinsuke Yamanaka, and G. Jeffrey Snyder, “Enhancement of Thermoelectric Efficiency in PbTe by Distortion of the Electronic Density of States,” Science, Vol. 321, pp. 554-558 (2008), incorporated herein in its entirety by reference.).

A recent study (V. Jovovic, S. J. Thiagarajan, J. P. Heremans, T. Komissarova, D. Khokhlov, and A. Nicorici, “Low temperature thermal, thermoelectric and thermomagnetic transport in indium rich Pb₁₋ₓSnₓTe alloys” J. Appl. Phys., Vol. 103, pp. 053710, 1-7 (2008), incorporated herein in its entirety by reference.), of a series of indium-doped PbTe samples confirms the result of the literature to date using thermoelectric and thermomagnetic measurements at 77 K. Recently, these measurements have been extended to 400 K (V. Jovovic, S. J. Thiagarajan, J. P. Heremans, T. Komissarova, D. Khokhlov, and A. Nicorici, “High-Temperature Thermoelectric Properties of Pb₁₋ₓSnₓTe:In” Mater. Res. Soc. Symp. Proc., Vol. 1044, pp. U04-09, Warrendale, Pa. (2008), incorporated herein in its entirety by reference.), and these measurements lead to the conclusion that the Fermi level, and thus the indium level, crosses into the energy gap at around 300 K, rendering the pinning effect on the Fermi level to be nil. At temperatures of 300 K or higher, the indium level does not contribute to the Seebeck coefficient or ZT.

In an investigation of the infrared absorption properties of thallium-doped PbTe, a similar pinning effect was reported (N. Veis, S. A. Nemov, V. A. Polovinkin and Yu. I. Ukhanov, Sov. Phys. Semicond., Vol. 11, pp. 588 (1977)) where the Fermi level is pinned in the valence band, and at a deeper level (100 meV below the top of the valence band). Such results raise the possibility that the temperature coefficient of thallium-doped PbTe may either have the opposite sign as does the temperature coefficient of indium-doped PbTe and the impurity level might actually sink deeper into the valence band, or that at least the temperature at which the impurity level crosses into the gap might be raised. Contrary to certain embodiments described herein, Kaidanov et al. (V. I. Kaidanov, S. A. Nemov, R. B. Melnik, A. M. Zaitzev and O. V. Zhukov, Sov. Phys. Semicond, Vol. 20, pp. 541 (1986)) reported an observation of a Seebeck coefficient of 120 μV/K at 300 K at a carrier concentration of p=1.16×10¹⁹ cm⁻³. Such a Seebeck coefficient is practically on the known curve for non-doped PbTe (e.g., 125 μV/K).

Without being bound by theory, certain embodiments described herein utilize a significantly higher thallium doping level to achieve an advantageous feature of the density of states near (e.g., within kT of) the Fermi level in thallium-doped PbTe. For example, as described more fully below, the energy derivative of the density of states can have one or more maxima or peaks, and the Fermi level of the compound can be located within kT of one of the maxima or peaks. In certain embodiments, at least one of gallium, aluminum, zinc, and cadmium can also be used to dope PbTe to have similar behavior (impurity resonance levels for thallium, gallium, zinc, and cadmium in PbTe have previously been calculated (S. Ahmad, S. D. Mahanti, K. Hoan and M G. Kanatizidis, Phys. Rev. B, Vol. 74, pp. 155205 (2006))).

Certain embodiments described herein provide a thermoelectric device comprising a doped compound semiconductor of at least one Group IV element (e.g., Si, Ge, Sn, or Pb) and at least one Group VI element (e.g., O, S, Se, or Te). In certain embodiments, the compound is a doped intermetallic compound semiconductor. In certain embodiments, the compound is doped with at least one dopant selected from the group consisting of indium, thallium, gallium, aluminum, and chromium.

In certain embodiments, the at least one Group VI element comprises at least two elements selected from the group consisting of: tellurium, selenium, and sulfur. For example, the compound of certain embodiments comprises PbTe₁₋ₓSeₓ, with x between 0.01 and 0.99, between 0.05 and 0.99, between 0.01 and 0.5, or between 0.05 and 0.5. In certain such embodiments, the at least one Group IV element comprises lead and at least one element selected from the group consisting of: germanium and tin. For example, the compound of certain embodiments comprises at least one compound selected from the group consisting of: Pb_{1-y}Sn_{y}SeₓTe₁₋ₓ, Pb_{1-y}Sn_{y}SₓTe₁₋ₓ, Pb_{1-y}Sn_{y}SₓSe₁₋ₓ, Pb_{1-y}Ge_{y}SeₓTe₁₋ₓ, Pb_{1-y}Ge_{y}SₓTe₁₋ₓ, Pb_{1-y}Ge_{y}SₓSe₁₋ₓ, where x is between 0.01 and 0.99, between 0.05 and 0.99, between 0.01 and 0.5, or between 0.05 and 0.5, and y is between 0.01 and 0.99, between 0.05 and 0.99, between 0.01 and 0.5, or between 0.05 and 0.5. In certain embodiments, the at least one dopant is selected from the group consisting of: at least one Group IIa element, at least one Group IIb element, at least one Group Ia element, at least one Group IIIb element, at least one lanthanide element, and chromium. In certain embodiments, the compound has a thermoelectric figure of merit, ZT (=TS²σ/κ), greater than 0.7 at temperatures greater than 500K. In certain embodiment, the at least one Group IV element is on a first sublattice of sites and the at least one Group VI element is on a second sublattice of sites, wherein the at least one Group IV element comprises at least 95% of the first sublattice sites. In certain such embodiments, the first sublattice is a metal sublattice which comprises the sites in which metal atoms reside in a defect-free compound of the at least one Group IV element and the at least one Group VI element. In certain embodiments, the second sublattice comprises the sites in which the at least one Group VI elements reside in a defect-free compound of the at least one Group IV element and the at least one Group VI element.

In certain embodiments, the compound comprises a p-type thermoelectric material with a peak figure of merit value greater than 0.7 at temperatures greater than 500 K, greater than 1 at temperatures greater than 580 K, or greater than 1.4 at temperatures at temperatures greater than 770 K. In certain other embodiments, the compound comprises an n-type thermoelectric material with a peak figure of merit value greater than 1.1 at temperatures greater than 500 K. In certain embodiments, the compound has a peak figure of merit value greater than 1.4 at a temperature greater than 700 K.

In certain embodiments, the intermetallic compound semiconductor has an improved thermoelectric figure of merit by the addition of small amounts (e.g., between about 0.1 atomic % to about 5 atomic %) of one or more dopant elements selected from Group IIa (e.g., Be, Mg, Ca, Sr, and Ba), Group IIb (e.g., Zn, Cd, and Hg), Group IIIa (e.g., Sc, Y, La), Group IIIb (e.g., Al, Ga, In, and Tl), and the lanthanides (e.g., La, Ce, Pr, Nd, Pm, Sm, Eu, Gd, Tb, Dy, Ho, Er, Tm, Yb, Lu). In certain various embodiments, the atomic doping concentration is in a range between about 0.1 atomic % and about 5 atomic %, between about 0.2 atomic % and about 5 atomic %, between about 0.4 atomic % and about 2 atomic %, between about 0.4 atomic % and about 1 atomic %, or between about 0.4 atomic % and about 0.8 atomic %. For example, for a thallium-doped material, the thallium atomic concentration can be in a range between about 0.5 atomic % to about 2 atomic % or in a range between about 0.1 atomic % to about 5 atomic %, either as a substitute for atoms of the at least one Group IV element or in addition to the at least one Group IV element. The dopant elements are advantageously selected to be elements that create hybridized deep resonant levels in the intermetallic compound. Certain embodiments provide improved ZT values in various ranges of temperatures depending on the chemical nature of the resonant level induced by the dopant element, and the chemical nature of the host IV-VI semiconductor compound.

In certain embodiments, the IV-VI semiconductor compound is doped with two or more dopant elements. For example, at least one first dopant comprises at least one element selected from the group consisting of indium, thallium, gallium, aluminum, and chromium and at least one second dopant comprises at least one element selected from the group consisting of lithium, sodium, iodine, bromine, and silver can be used. In certain such embodiments, the iodine or bromine can be added as PbI₂ or PbBr₂. Ga-doped PbTe is n-type, and the halogens can be used as n-type dopants for PbTe:Ga. As another example, at least one first dopant comprises at least one element selected from the group consisting of indium, thallium, gallium, aluminum, and chromium and at least one second dopant comprising an excess amount of the at least one Group VI element (e.g., Te, Se, or S) can be used. In certain such embodiments, the atomic concentration of the at least one Group VI element is greater than the atomic concentration of the at least one Group IV element and the excess amount of the at least one Group VI element is equal to a difference between the atomic concentration of the at least one Group VI element and the atomic concentration of the at least one Group IV element.

In certain embodiments, the at least one Group IV element comprises lead, the at least one Group VI element comprises tellurium, and the at least one dopant comprises thallium with a dopant concentration in a range between about 0.5 atomic % and about 5 atomic %. In certain embodiments, the at least one Group IV element comprises at least one element selected from the group consisting of lead and tin, the at least one Group VI element comprises tellurium, and the at least one dopant comprises thallium. In certain embodiments, the at least one Group IV element comprises lead, the at least one Group VI element comprises tellurium, and the at least one dopant comprises at least one element selected from the group consisting of thallium and sodium. In certain such embodiments, the thallium concentration is in a range between about 0.5 atomic % and about 5 atomic %, and the sodium concentration is in a range between about 0.5 atomic % and about 5 atomic %. In certain embodiments, the at least one Group IV element comprises lead, the at least one Group VI element comprises tellurium, and the at least one dopant comprises at least one of gallium and one or more additional dopant selected from the group consisting of: a halogen (e.g., chlorine, iodine, and bromine), bismuth, and antimony. In certain such embodiments, the gallium concentration is in a range between about 0.5 atomic % and about 5 atomic %, and the halogen concentration is in a range between about 0.5 atomic % and about 5 atomic %. In certain embodiments (e.g., for PbTe:Ga or PbTe:Al), the double doping of either Ga or Al with a halogen, bismuth, or antimony advantageously provides an n-type material. For PbTe:Ga, Volkov et at (B. A. Volkov, L. I. Ryabova, and D. R. Khokhlov, Physics-Uspekhi, Vol. 45, pp. 819 (2002)), describes that there are two saturation regions: one with a low electron density, and one at a higher electron density. Certain embodiments described herein are in the higher electron density regime, which is achieved by adding iodine, bromine, bismuth, or antimony as an n-type dopant. In certain embodiments in which the dopant element comprises gallium (e.g., for PbTe doped with gallium), the atomic concentration of the Group IV-Group VI compound deviates toward the Group IV-rich side, with Group IV atomic concentration greater than the Group VI atomic concentration by an amount in the range between about 0.1 atomic % to about 0.5 atomic %. In certain such embodiments, the Ga-doped, Pb-rich PbTe is advantageously used as an n-type thermoelectric material with improved ZT.

In certain embodiments, the compound comprises a first atomic concentration of the at least one Group IV element and a second atomic concentration of the at least one Group VI element, and the first atomic concentration and the second atomic concentration are within about 2% of one another (e.g., either Group IV- or metal-rich or Group VI- or chalcogen-rich). In certain embodiments, the compound comprises a first atomic concentration of the at least one Group IV element and a second atomic concentration of the at least one Group VI element, and the first atomic concentration is less than the second atomic concentration.

In certain embodiments, the at least one dopant further comprises at least one metal element. For example, the at least one metal element comprises at least one of at least one alkali metal element (e.g., lithium, sodium, potassium, rubidium, and cesium) and at least one noble metal element (e.g, silver, copper, and gold).

In certain embodiments, a thermoelectric device comprises a doped Group IV chalcogenide compound doped with at least one dopant such that a resonant level is formed in an energy band of the compound and the Fermi level of the compound is at an energy within kT of the resonant level. In certain embodiments, the doped Group IV chalcogenide compound comprises at least one Group IV element selected from the group consisting of lead, tin, germanium, and silicon. In certain embodiments, the doped Group IV chalcogenide compound comprises at least one Group VI chalcogen selected from the group consisting of tellurium, selenium, sulfur, and oxygen.

In a previous study by Kaidanov et al (V. I. Kaidanov, E. K. Iordanishvili, V. N. Naumov, S. A. Nemov and Yu. I. Ravich, Sov. Phys. Semicond., Vol. 20, pp. 693-694 (1986)), PbTe double-doped with both thallium and sodium was observed to have an increased thermoelectric power. The Seebeck coefficient was observed to reach up to 140 μV/K, a three-to-four-fold improvement over the performance of PbTe doped to similar carrier densities with sodium alone. This result was achieved while decreasing the electrical conductivity of the material only by a factor of 2. In certain embodiments described herein, a major constituent of the at least one Group IV element is not lead (e.g., lead is less than 5% of the at least one Group IV element, or lead is less than 2% of the at least one Group IV element). In certain other embodiments, a major constituent of the at least one Group VI element is not tellurium (e.g., tellurium is less than 5% of the at least one Group VI element, or tellurium is less than 2% of the at least one Group VI element). In certain other embodiments, the thermoelectric material is not appreciably doped with sodium.

These results were attributed by Kaidanov et al. to be the result of a phenomenon they called “resonant scattering”. In a subsequent paper, Kaidanov et al. (V. I. Kaidanov, S. A. Nemov and Yu. I. Ravich, Sov. Phys. Semicond., Vol. 26, pp. 113 (1992)) stated explicitly that such double-doping is necessary to increase ZT. A subsequent review article by Ravich (Y. I. Ravich, “Selective Carrier Scattering in Thermoelectric Materials”, Chapter 7, pp. 67-81, in CRC Handbook of Thermoelectrics, D. M. Rowe, editor, CRC Press, Boca-Raton Fla., 1995) repeats that adding both thallium and sodium at 1% levels in PbTe is necessary to increase the thermoelectric figure of merit ZT. These statements by Kaidanov et al. and Ravich are based on the effect of increasing the energy dependence of the relaxation time, and thus the second term, or mobility term dμ/dE, in the Mott relation as expressed by equation (2). The mobility term dμ/dE is dependent on temperature. This concept leads Ravich to explicitly teach (see, page 70 of Ravich) that such a mechanism is only effective at low temperatures, where phonon-electron scattering is less effective, and thus “resonant scattering” is relatively more effective. Additionally, this concept has led the prior literature to concentrate on improving ZT below room temperature using this mechanism.

In contrast, without being bound by theory, certain embodiments described herein utilize the first term of the Mott relation, as expressed by equation (2), dn/dE to advantageously provide compounds having a temperature-independent improvement of their thermoelectric properties. In some embodiments, dn/dE at or near (e.g., within kT of) the Fermi level is advantageously maximized. In addition, certain embodiments described herein provide a much improved peak ZT(e.g., greater than 0.7) at temperatures above room temperature (e.g., above 300 K) or higher (e.g., above 500K) since the Seebeck coefficient of degenerately-doped semiconductors is proportional to temperature.

Contrary to the explicit teachings of Ravich, certain embodiments described herein do not utilize double-doping with thallium and sodium. Certain such embodiments utilize p-type thallium-doped PbTe, without double-doping with Na, to provide large improvements in ZT at temperatures significantly above room temperatures. To improve ZT by doping the PbTe compound with a single dopant element, it is desirable to have both a hybridized level and an appropriate hole density. Thallium is a known acceptor in PbTe, and a hybridized level is created spontaneously, in contradiction to the teachings of the cited literature, provided that the thallium impurity is added in an appropriate concentration. This concentration (e.g., on the order of about 0.1 atomic % to about 2 atomic %) depends on the stoichiometry of the parent material (e.g., the ratio of metal Pb to chalcogen Te for PbTe), and in certain embodiments, the concentration range can be broadened by adding extra tellurium.

In certain embodiments, compounds doped with gallium provide n-type IV-VI thermoelectric materials with improved ZT. In certain such embodiments, the stoichiometry of the parent IV-VI compound is advantageously adjusted. For example, for PbTe doped with gallium, the parent compound can be made slightly Pb-rich (e.g., with an additional Pb concentration on the order of 2×10¹⁹ to 1×10²⁰ cm⁻³) (see, e.g., G. S. Bushmarina, B. F. Gruzinov, I. A. Drabkin, E. Ya. Lev and I. V. Nelson, Sov. Phys. Semicond. 11 1098(1978)).

In certain embodiments, nano-scale thermoelectric materials comprising semiconductor compounds with charge carriers at or near (e.g., within kT of) hybridized energy levels are provided. Resonant scattering is known to limit the electron mobility in tellurium-doped PbTe to values below perhaps 100 cm²/Vs (V. I. Kaidanov, S. A. Nemov and Yu. I. Ravich, Sov. Phys. Semicond., Vol. 26, pp. 113 (1992). Consequently, the electron mean free path in such materials is already very short (e.g., on the order of a few interatomic spacings, or 1-2 nanometers). This conclusion is likely generalized to all semiconductors in which the carriers are in or close to (e.g., within kT of) a strong distortion of the density of states, such as induced by hybridized resonant levels. Preparing the thermoelectric material in the form of nanometer-sized grains, sintered or otherwise attached together, which might scatter these electrons, is not likely to decrease the mobility much further. However, such a morphology will scatter the phonons responsible for the lattice thermal conductivity, resulting in a strong decrease in thermal conductivity without the concomitant deleterious effect on the electrical conductivity. In certain embodiments, the thermal conductivity is reduced by about one-third (see, e.g., F. Ioffe, Physics of Semiconductors (Academic Press, New York, 1960)). Therefore, semiconductor compounds with charge carriers at or near hybridized resonant energy levels and in which resonant scattering such as described by Kaidanov et al. and Ravich is effective, are prime candidates for being prepared as nano-scale thermoelectric materials (e.g., with grains or particles having dimensions in a range between about 1 nanometer and about 100 nanometers).

Like nanoparticles scattering above, alloy scattering is known to reduce the mean free path of both electrons and phonons (see, e.g., B. Abeles, Phys Rev., Vol. 131, pp. 1906 (1963)). Since the mean free path of electrons near a resonant level is already short, alloy scattering will not shorten it much more, but it will very effectively scatter phonons. In certain embodiments, the thermoelectric material has alloy scattering.

### EXAMPLE

### Tl_{0.01}Pb_{0.99}Te and Tl_{0.02}Pb_{0.98}Te

Sample materials were formulated and their properties measured. This work was described in Joseph P. Heremans, Vladimir Jovovic, Eric S. Toberer, Ali Saramat, Ken Kurosaki, Anek Charoenphakdee, Shinsuke Yamanaka, and G. Jeffrey Snyder, “Enhancement of Thermoelectric Efficiency in PbTe by Distortion of the Electronic Density of States,” Science, Vol. 321, pp. 554-557 (2008), which is incorporated herein in its entirety by reference. Several disk-shaped samples of Tl_{0.01}Pb_{0.99}Te and Tl_{0.02}Pb_{0.98}Te were prepared and mounted for high-temperature measurements (300 to 773 K) of their conductivity (σ and κ), as well as Hall (R_{H}) and Seebeck (S) coefficients; parallelepipedic samples were cut from the disks and mounted for low-temperature measurements (77 K to 400 K) of galvanomagnetic (ρ and R_{H}) and thermomagnetic (S and N, which stands for the isothermal transverse Nernst-Ettingshausen coefficient) properties

Tl-doped PbTe was made by direct reaction of appropriate amounts of Pb, Te, and Tl₂Te in a fused-silica tube sealed under a vacuum. Each sample was melted at 1273 K for 24 h and lightly shaken to ensure homogeneity of the liquid. Each sample was then furnace cooled to 800 K and annealed for 1 week. The obtained ingot was crushed into fine powder and hot-pressed at 803 K for 2 hours under a flowing 4% H₂—Ar atmosphere. The final form of each polycrystalline sample was a disk with a thickness of about 2 mm and a diameter of about 10 mm. Phase purity was checked by powder X-ray diffraction. No impurity phases were found in the XRD patterns, indicating that substantially all T1 was dissolved in PbTe. The purity of the starting materials was at least about 99.99%. The samples were stable in air at room temperature. Parallelepipeds were cut out of the disks and were typically about 8 mm long with a cross-section of about 1×1 mm². Other methods of processing can also be used such as ball milling and mechanical alloying.

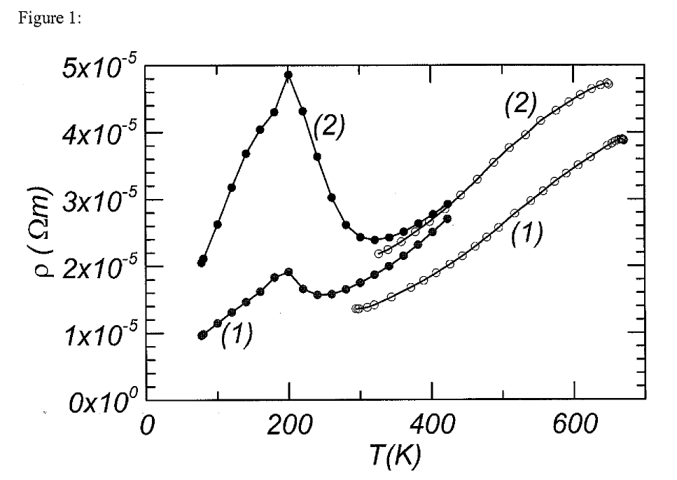

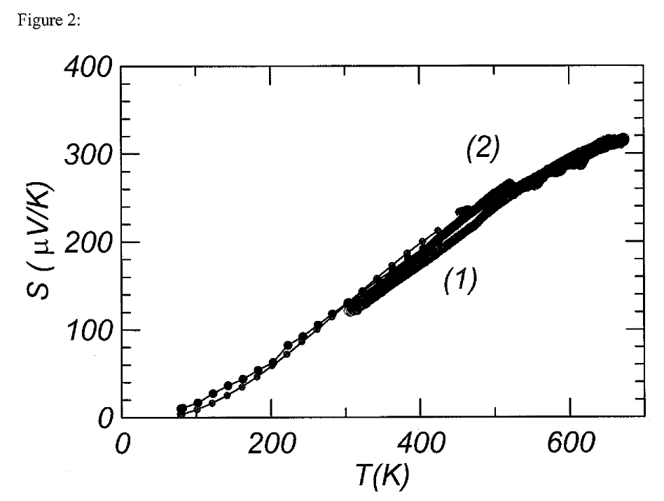

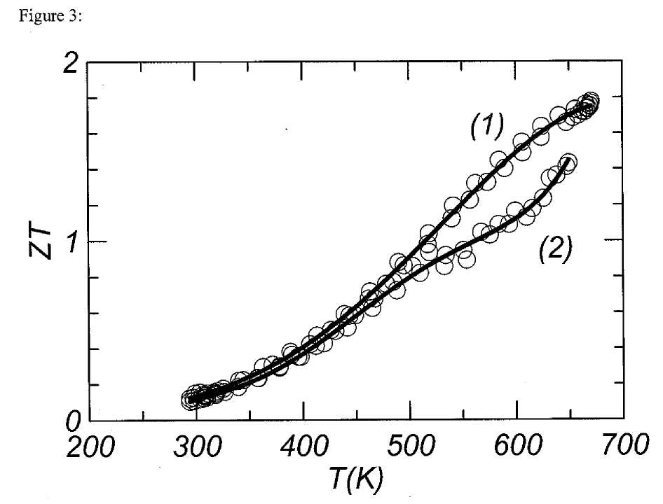

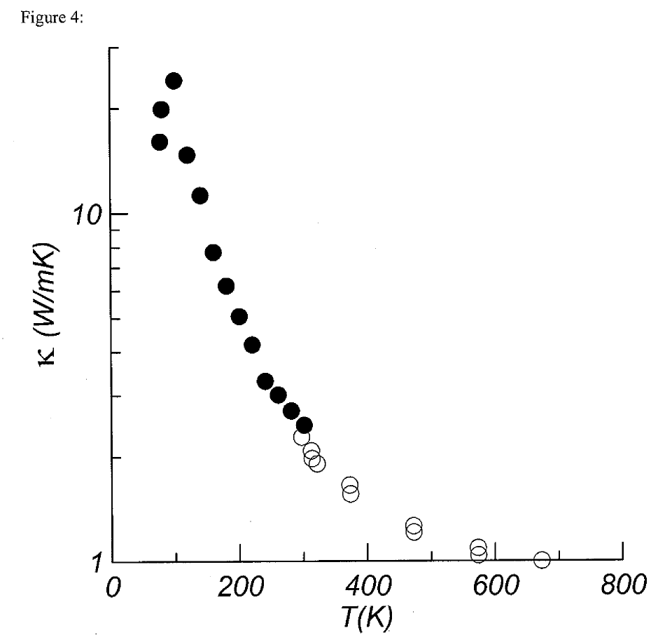

FIG. 1 is a plot of the temperature dependence of the resistivity of thallium-doped lead telluride. The curves labeled (1) are for a sample with 1 atomic % thallium, and the curves labeled (2) are for a sample with 2 atomic % thallium. The open dot curves were taken from 300 to 670 K on disk-shaped samples. The closed dot curves were measured from 77 to 400 K on parallelepiped cut-outs of the disks. FIG. 2 is a plot of the temperature dependence of the Seebeck coefficients of the samples of FIG. 1. FIG. 3 is a plot of the temperature dependence of the calculated figure of merit ZT (=TS²σ/κ) from the data of FIGS. 1 and 2. FIG. 4 is a plot of the temperature dependence of the thermal conductivity of the sample with 2 atomic % thallium. The thermoelectric figure of merit ZT versus temperature shown in FIG. 3 shows a significant improvement as compared to conventional thermoelectric materials (e.g., for temperatures greater than 300 K). For example, at 500 K, both Tl_{0.01}Pb_{0.99}Te and Tl_{0.02}Pb_{0.98}Te have values of ZT greater than 0.7, and the figure of merit, ZT, for both Tl_{0.01}Pb_{0.99}Te and Tl_{0.02}Pb_{0.98}Te increases with increasing temperature from 300 K to at least 650 K. The figure of merit for Tl_{0.01}Pb_{0.99}Te has a peak figure of merit value of about 0.85 at a temperature of about 670 K. The figure of merit for Tl_{0.02}Pb_{0.98}Te does not appear in FIG. 3 to have a peak at temperatures less than 773 K; however, it is expected that the figure of merit for this compound will decrease at some temperature greater than 773 K, so that the compound has a peak figure of merit value of at least 1.5 at a temperature greater than or equal to 773K.

The high-temperature electrical resistivity, ρ, and Hall coefficient, R_{H}, (in a 2T magnetic field) were measured between 300 K and 773 K on the pressed disks using the van der Pauw technique with a current of 0.5 A under dynamic vacuum (similar to the system described by McCormack, J. A. and Fleurial, J. P., Mater, Res. Soc. Symp. Proc., Vol. 234, pp. 135 (1999)). The Seebeck coefficient S=V/ΔT was measured between 300 K and 773 K on the pressed disks using Chromel-Nb thermocouples with the Nb wires used for voltage measurement. The thermocouples were heat sunk to the heaters contacting the sample to minimize heat leaks through the thermocouples. An about constant 10 K temperature difference was maintained with Proportional-Integration-Differentiation control while the system was uniformly heated and cooled at 100K/hr. The absolute Nb voltage was subtracted from the measured voltage. The Chromel-Nb Seebeck coefficient was derived from measurements of the individual metals compared to Pt. The thermal diffusivity of the disks was measured using a flash diffusivity technique, Netzsch LFA 457. Heat capacity, Cₚ, was estimated using the method of Dulong-Petit with a value of 0.15 J/g·K, which was close to the experimental value from 150 to 270 K (D. H. Parkinson and J. E. Quarrington, Proc. Phys. Soc., Vol. 67, pp. 569 (1954)). The thermal conductivity, κ, was then calculated from the experimental density, heat capacity, and thermal diffusivity. The thermal conductivity of all the samples was about the same and within the experimental errors, and the thermal conductivity of the samples was similar to that of bulk PbTe at similar electrical conductivity (see, e.g., A. D. Stuckes, Br. J. Appl. Phys., Vol. 12, pp. 675 (1961)).

The repeatability of Seebeck, electrical resistivity, and diffusivity measurements as determined from the difference between heating and cooling curves and was within 3 to 5%. The reproducibility, as determined from measurements using different contacts or with different slices from the same pellet, is about 10% with larger uncertainty at higher temperatures. From these combined uncertainties, the estimated uncertainty in maximum ZT is about 20%. In the TlₓPb₁₋ₓTe system, different samples measured with maximum ZT values ranging between 1.2 and 1.9, which were consistent with our estimate of maximum ZT=1.5±0.3.

Between 77 K and 400 K, ρ and R_{H} were measured on two parallelepipedic samples with one cut in the plane of the disk and one perpendicular to it, to verify that the samples were isotropic. The measurements were made using a low-frequency AC bridge, and by taking the appropriate average over both polarities of the magnetic field (−1.8 to 1.8 T), which was a procedure appropriate for the rock-salt crystal structure of PbTe, which excludes Umkehr effects. The Hall coefficient was taken as the slope at zero magnetic field of the transverse Hall resistivity with respect to field. The inaccuracy in sample dimensions, particularly in the distance between the longitudinal probes, is the main source of experimental inaccuracy, and the relative error on the electrical resistivity is on the order of 10%. The Hall coefficient depends on the transverse dimension and is accurate within 3%.

Between 77 K and 400 K, the Seebeck, S, and isothermal Nernst-Ettingshausen, N, coefficients were measured on the parallelepipeds using a static heater and sink method. Similar to above, reversing the sign of the magnetic field has no expected Umkehr effects. The Seebeck coefficient does not generally depend on the sample geometry, and measurement accuracy is limited mostly by the sample uniformity to 5%. The adiabatic Nemst-Ettingshausen coefficient was taken as the slope at zero magnetic field of the transverse Nernst thermoelectric power with respect to field, and the isothermal Nernst coefficient, N, was calculated from the adiabatic one (following the procedure described by J. P. Heremans, C. M. Thrush and D. T. Morelli, J. Appl. Phys., Vol. 98, pp. 063703 (2005)). The Nernst data had about 10% accuracy, limited by the longitudinal distance between the temperature probes.

The thermal conductivity was also measured from 77 K to 300 K using a static heater and sink method on two parallellepipedic samples cut from the same disk of Tl_{0.1}Pb_{0.99}Te both in the plane and perpendicularly to the plane of the disk. The thermal conductivity was found to be isotropic, and also corresponded well to that measured by the diffusivity method. The isotropy of the electrical conductivities was also verified experimentally.

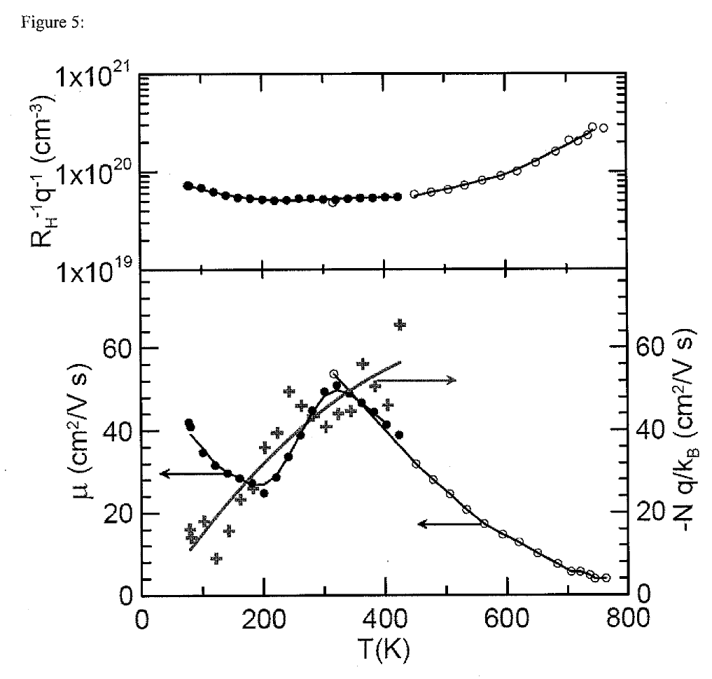

The results for the zero-field transport properties on representative Tl_{0.01}Pb_{0.99}Te and Tl_{0.02}Pb_{0.98}Te samples are shown in the main text. The properties in a transverse magnetic field, the low-field Hall and Nernst coefficients, are shown in FIG. 5. The Hall coefficient is shown in FIG. 5 inverted, R_{H}⁻¹, and in units of hole density. The Nernst coefficient, N, is in units V/K·T and is shown in FIG. 5 divided by the Seebeck coefficient of the free electron, k_{B}/q, where q is the electron charge. In addition, since units of 1/Tesla are those of the mobility, it is represented it in the same units and on the same scale as the Hall mobility.

The “method of the four coefficients”, developed to deduce Hall mobility, μ, scattering exponent, Λ, density of states effective mass, m*_{d}, and the Fermi energy, E_{F}, from measurements of ρ, R_{H}, S and N, has been adapted to degenerately doped semiconductors (see, e.g., V. Jovovic, S. J. Thiagarajan, J. West, J. P. Heremans, T. Story, Z. Golacki, W. Paszkowicz and V. Osinniy, J. Appl. Phys., Vol. 102, pp. 043707 1-6 (2007)). The different materials parameters μ, Λ, m*_{d} and E_{F} have different sensitivities to the different thermomagnetic transport coefficients ρ, R_{H}, S and N. The conclusions presented are quite independent of the band model used. No integrations have to be performed over assumed band structures or dispersion relations, and Bethe-Sommerfeld expansions of the transport properties are analytically solvable for μ, Λ, m*_{d} and E_{F} at the Fermi energy. No numerical manipulations are required in this case.

At temperatures below 450 K, the R_{H} coefficient directly gives the carrier density via n=1/(R_{H}q), and the ratio of Hall coefficient over resistivity gives the mobility μ=R_{H}/ρ as shown in FIG. 5. At temperatures above 500 K, the Hall coefficient decreases with increasing temperature. The reason for this is the onset of two-carrier conduction. Thermally induced minority electrons have a partial Hall coefficient that has the opposite polarity of the partial Hall coefficient of the holes. Therefore, the carrier density above 450K can not be calculated using the above relationship. Generally, the Seebeck coefficient is practically not affected by the partial Seebeck of the minority electron. Equations that include two-carrier conduction (see, e.g., E. H. Putley The Hall Effect and Semiconductor Physics, Dover Publications, New York (1968)) illustrate this effect. While the total Seebeck coefficient is the average of the partial Seebeck coefficients of electrons and holes weighted by their partial electrical conductivities, the total Hall coefficient is weighted by electron and hole mobility square. The electron mobility is on the order of 550 cm²/Vs at 300K, which is larger than the hole mobility as shown in FIG. 5. Therefore, the Hall coefficient is more sensitive to minority carriers than the Seebeck coefficient.

The scattering exponent, Λ, is derived from the ratio of the Nernst coefficient to the mobility as shown in FIG. 5. From their comparable magnitude and inverted signs, the scattering exponent, Λ, varies slightly from about −½ to about zero, which is similar to pure PbTe with acoustic phonon and neutral impurity scattering as the dominant scattering mechanisms. The Fermi energy can then be derived from the Seebeck coefficient. From the Fermi energy and carrier density, the local density of states g_{eff}(E_{F}) or the density of states effective mass m*_{d} defined by the relation g_{eff}=4×2×(2π m*_{d})^{3/2}/h³, where the initial factor of 4 represents the number of degenerate hole pockets that constitute the Fermi surface of heavily doped PbTe, and h is Planck's constant, can be calculated. The effective mass can be used to characterize a dispersion relation between the energy, E, and the wave number, k, of a carrier that is parabolic because the effective mass is constant with respect to energy. Since a distorted band is characterized in the case of Tl_{0.02}Pb_{0.98}Te and of Tl_{0.01}Pb_{0.99}Te, m*_{d} is used as a parameterization of the local density of states at the Fermi level, and used to quantify the relative increase of the density of states of Tl—PbTe when compared to that of pure PbTe.

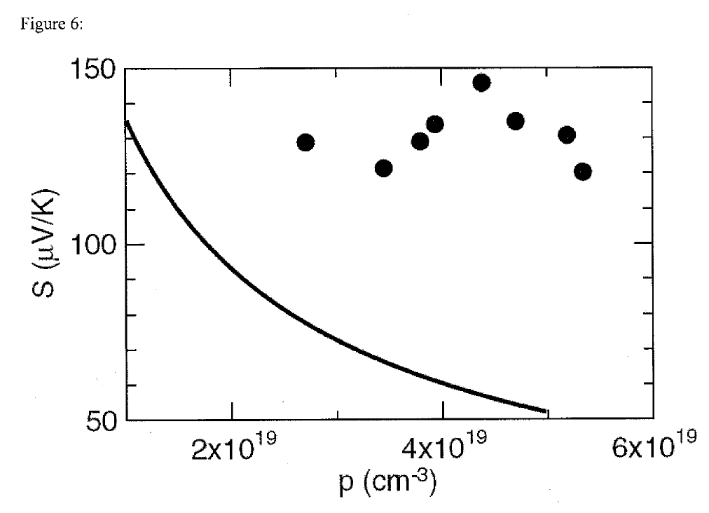

FIG. 6 is a plot of the Seebeck coefficient versus carrier density at a temperature of 300 K, with the value for the sample measured so far shown as the circle datapoints and the Pisarenko curve valid for conventionally doped PbTe shown as the solid curve. FIG. 6 indicates that the enhanced thermoelectric properties are due to a substantial increase of the Seebeck coefficient at the carrier concentration measured from the sample over that of the Pisarenko curve valid for conventionally doped PbTe,

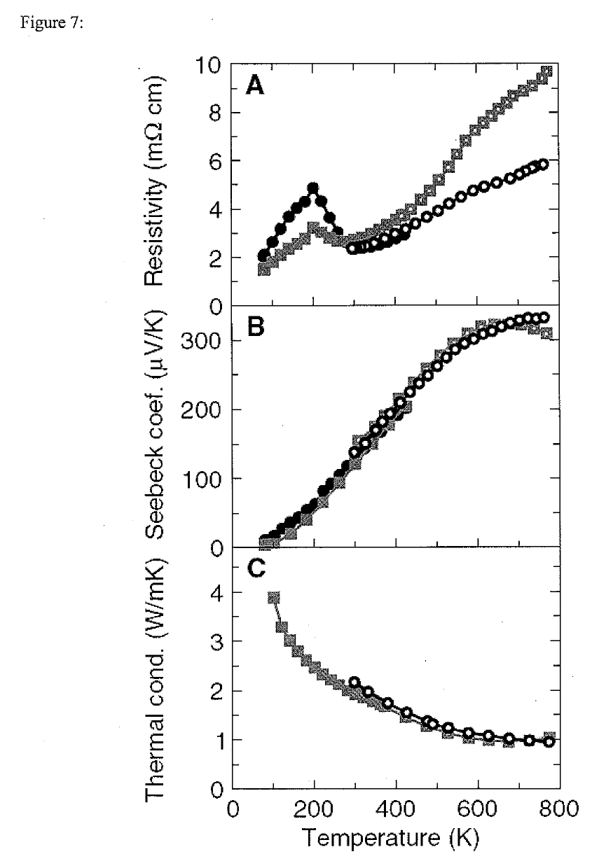

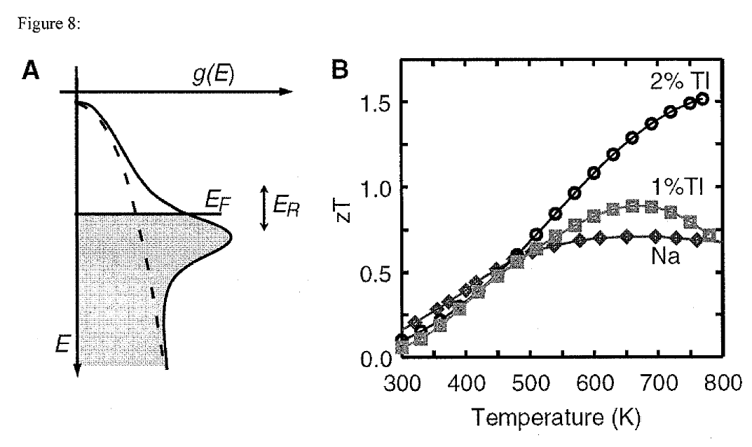

Further results for the zero-field transport properties (i.e., electrical resistivity, Seebeck coefficient, and thermal conductivity) measured on representative samples of Tl_{0.01}Pb_{0.99}Te and Tl_{0.02}Pb_{0.98}Tc are shown in FIG. 7. Values of ZT for Tl_{0.02}Pb_{0.98}Te reach 1.5 at 773 K as shown in FIG. 8B. The high value of ZT observed is quite reproducible and robust with respect to slight variation in dopant concentration in Tl_{0.02}Pb_{0.98}Te. The uncertainty in ZT is estimated to be on the order of 7% near room temperature and increasing at higher temperature, assuming that the inaccuracies on S, σ and κ are independent of each other. For Tl_{0.01}Pb_{0.99}Te, the decreased doping levels lead to a lower carrier concentration and a corresponding increase in S and ρ. The values in FIG. 8B represent a 100% improvement of the ZT compared with the best conventional p-type PbTe-based alloys (ZTₘₐₓ=0.71 for Na_{0.01}Pb_{0.99}Te, see, e.g., R. W. Fritts, in Thermoelectric Materials and Devices, I. B. Cadoff, E. Miller, Eds. (Reinhold, New York, 1960), pp. 143-162). The maximum in ZT in certain embodiments occurs at the temperature where thermal excitations start creating minority carriers. This maximum is not reached by 773 K for Tl_{0.02}Pb_{0.98}Te, and thus, in certain embodiments, higher values of ZT may be expected.

The temperature range where these PbTe based materials of certain embodiments exhibit high ZT values (500 to 773 K) is appealing for power generation from waste heat sources such as automobile exhaust. These measurements did not include direct thermoelectric efficiency measurements because of the nontrivial conditions for a matching n-type material, good thermal isolation, and low thermal and electrical contact resistance. The latter consideration arises because the main flow of heat and of electrical current generally passes through the contacts of a TE power generator, in contrast to the situation in the experiments reported here.

The measured K values of Tl—PbTe samples reproduce that of pure bulk PbTe (Yu. I. Ravich et al., Semiconducting Lead Chalcogenides (Plenum, New York, 1970)). In contrast, ZT-enhancing mechanisms used previously in PbTe-based materials have relied on minimizing the lattice thermal conductivity (G. J. Snyder, E. S. Toberer, Nat. Mater., Vol. 7, pp. 105 (2008); K. F. Hsu et al., Science, Vol. 303, pp. 818 (2004); J. Androulakis et al., Adv. Mater., Vol. 18, pp. 1170 (2006); P. F. R. Poudeu et al., Angew. Chem. Int, Ed., Vol. 45, pp. 3835 (2006)). The slight rise in κ of the Tl_{0.02}Pb_{0.98}Te sample at high temperatures is attributed to ambipolar thermal conduction.

Hall and Nernst coefficients were analyzed to elucidate the physical origin of the enhancement in ZT. The Hall coefficient R_{H} of Tl_{0.02}Pb_{0.98}Te is nearly temperature independent up to 500 K, corresponding to a hole density of 5.3×10¹⁹ cm⁻³. The room temperature hole mobility μ (μ=R_{H}/ρ) for Tl_{0.02}Pb_{0.98}Te varies from sample to sample between 50 and 80 cm²/Vs and is a factor of 5 to 3 smaller than the mobility of single-crystal PbTe at similar carrier concentrations but has a similar temperature dependence.

Typically S depends strongly on carrier density as shown by Equation 3:

$$S = \frac{8 {π}^{2} {k}_{B}^{2} T}{3 {qh}^{2}} {{m}_{d}^{*} ( \frac{π}{3 n} )}^{2 / 3} \qquad ( 3 )$$

The solid line of FIG. 6 was calculated given the known band structure and acoustic phonon scattering. It has been previously observed that almost every measurement published on n or p-type bulk PbTe falls on that line (see, e.g., Yu. I. Ravich et al., Semiconducting Lead Chalcogenides (Plenum, New York, 1970)). Compared to this, S of Tl—PbTe at 300 K is enhanced at the same carrier concentration, as shown graphically in FIG. 6, which plots data on every Tl—PbTe sample measured in this study. Each of these samples shows an enhancement in S by a factor of between 1.7 and 3, which, in Tl_{0.02}Pb_{0.98}Te samples, more than compensates for the loss in mobility in ZT. The enhancement increases with carrier density, and indeed so does the ZT.

Referencing Eq. 2, S is a finction of the energy dependence of both the density of states and the mobility. The mobility can be represented in terms of a relaxation time τ and a transport effective mass m*:μ=qτ/m*. The energy dependence of the relaxation time (τ(E)=τ₀E^{Λ}) (Yu. I. Ravich et al., Semiconducting Lead Chalcogenides (Plenum, New York, 1970)) is taken to be a power law, with the power, the scattering exponent L, determined by the dominant electron scattering mechanism. Acoustic phonon scattering in a three-dimensional solid is characterized by Λ=−½.

Nernst coefficient measurements can be used to determine the scattering exponent Λ and to decide which of the two terms in Eq. 2 dominates. The “method of the four coefficients” (J. P. Heremans et al., Phys. Rev. B, Vol. 70, pp. 115334 (2004)) was used to deduce μ, Λ, m*_{d} and E_{F} from measurements of ρ, R_{H}, S, and N. No increase was observed in Λ over its value (−½) in pure PbTe as would be expected from the “resonant scattering” hypothesis (Yu. I. Ravich, in CRC Handbook of Thermoelectrics, D. M. Rowe, Ed. (CRC Press, Boca Raton, Fla., 1995), pp. 67-81). Furthermore, the effects of resonant scattering would be expected to vanish with increasing temperature, because acoustic and optical phonon scattering would then become ever more dominating. This would not only contradict the results of FIG. 8 but also preclude the use of such materials in any high-temperature applications such as electrical power generators. Thus, the teaching of prior work, such as that of Ravich and Kaidanov would lead to the conclusion that compounds in accordance with certain embodiments described herein would not provide high figure of merit at high temperature.

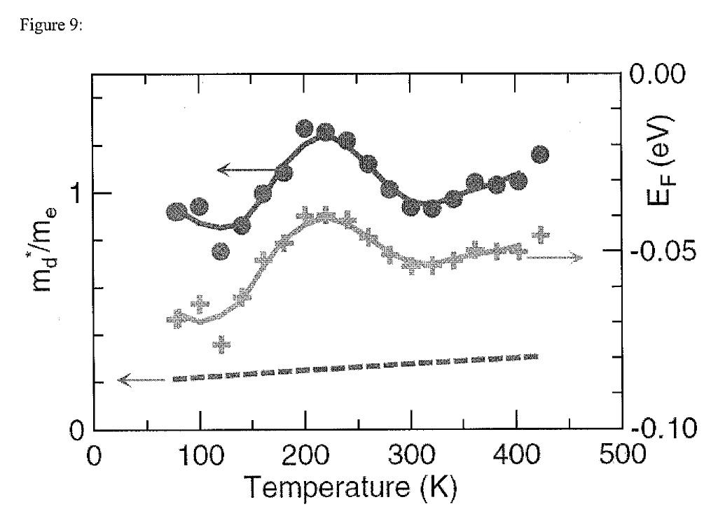

In contrast to the constant scattering exponent Λ, the method of four coefficients shows a factor of 3 increase in the effective mass (m*_{d}) over that of Na—PbTe (H. Preier, Appl. Phys. (Berl.), Vol. 20, pp. 189 (1979)), as shown in FIG. 9, calculated at E_{F}=50 meV for a classical nonparabolic band (Ravich et al.). As seen in Eq. 2, such an increase in m*_{d} will directly increase S by the same factor, as observed in these measurements. It is also consistent with the measurements of the electronic specific heat (Y. Matsushita et al., Phys. Rev. B, Vol. 74, pp. 134512 (2006)) as expected because both the specific heat and S are closely related to the entropy of the electrons (H. B. Callen, Thermodynamics (Wiley, New York, 1960)). The local increase in m*_{d} implies a decidedly nonparabolic perturbation in the electron dispersion relations and the density of states.

Because S and electronic heat capacity are sensitive to the change in the DOS at E_{F}, m*_{d} derived from these quantities is actually a measure of dn(E)/dE. The latter quantity will be enhanced for E_{F} close to the inflection point of the g(E) curve, as shown in FIG. 7A, which is closer to the valence band edge than the energy at which the DOS is maximum. Indeed, in certain embodiments, g(E) does not have a maximum in g(E). The measured value of E_{F} at 50 meV is consistent with this description, because the inflection point is expected to be near half the energy (˜30 meV in this case) at which a maximum in DOS is reported (S. A. Nemov et al., Physics-Uspekhi, Vol. 41, pp. 735 (1998)). In general, the sharper the local increase in DOS, the larger the enhancement in m*_{d} and in S. The agreement between the measurements of the enhancement in m*_{d}, specific heat, and our measured E_{F} for Tl—PbTe strongly supports this model as the source of enhanced S and ZT.

One feature observed in each of the measured Tl—PbTe samples is the local maximum in p near 200 K. It is attributed to a minimum in mobility that occurs at the same temperature at which the mass has a maximum. Thus, in certain embodiments, the maximum in ρ, or the minimum in μ, occurs at a temperature at which E_{F} nears an inflection point in the dispersion relation. Double-doping compounds to vary the Fermi energy can be used in accordance with certain embodiments described herein.

Further improvements in ZT are achievable in certain embodiments by systematically optimizing the location of EF compared to the shape of g(E), for instance, by co-doping the samples with both Tl and another acceptor impurity such as Na. In addition to opening a new route to high-ZT materials that is not limited by the concept of minimum κ, certain such embodiments do not rely on the formation of nanoparticles, which are subject to grain growth or dissolution into the host material during operation. The method is independent of phonon properties, implying that improvements in ZT induced by reducing the lattice κ value can work in conjunction with the optimization of the location of E_{F}. Deliberately engineered impurity-induced band-structure distortions can be a generally applicable route to enhanced S and ZT in certain embodiments described herein. The origin of the band structure distortions is not limited to the presence of resonant levels of dopant. Other mechanisms can result in the distortion of electronic density of states, delivering enhanced thermoelectric properties as described above. One such mechanism can be the interaction between different bands of the thermoelectric material, where the presence and/or electron population in at least one additional electronic band or state distorts the DOS in the first band, thereby yielding enhanced Seebeck coefficient.

Various embodiments have been described above. Although this invention has been described with reference to these specific embodiments, the descriptions are intended to be illustrative of the invention and are not intended to be limiting. Various modifications and applications may occur to those skilled in the art without departing from the true spirit and scope of the invention as defined in the appended claims.

What is claimed is:

1. A thermoelectric material comprising a doped compound of at least one Group IV element and at least one Group VI element, wherein the compound is doped with at least one dopant selected from the group consisting of: at least one Group IIa element, at least one Group IIb element, at least one Group IIIa element, at least one Group IIIb element, at least one lanthanide element, and chromium, wherein the at least one Group IV element is on a first sublattice of sites and the at least one Group VI element is on a second sublattice of sites, wherein the at least one Group IV element comprises at least 95% of the first sublattice sites, wherein the compound has a peak thermoelectric figure of merit ZT value greater than 0.7 at temperatures greater than 500 K.

2. The thermoelectric material of claim 1, wherein the at least one dopant comprises at least one Group IIa element selected from the group consisting of: beryllium, magnesium, calcium, strontium, or barium.

3. The thermoelectric material of claim 1, wherein the at least one dopant comprises at least one Group IIb element selected from the group consisting of: zinc, cadmium, or mercury.

4. The thermoelectric material of claim 1, wherein the at least one dopant comprises at least one Group IIIa element selected from the group consisting of: scandium, yttrium, or lanthanum.

5. The thermoelectric material of claim 1, wherein the at least one dopant comprises at least one Group IIIb element selected from the group consisting of: indium, thallium, gallium, or aluminum.

6. The thermoelectric material of claim 1, wherein the at least one dopant comprises at least one lanthanide element selected from the group consisting of: lanthanum, cerium, praseodymium, neodymium, promethium, samarium, europium, gadolinium, terbium, dysprosium, holmium, erbium, thulium, ytterbium, or lutetium.

7. The thermoelectric material of claim 1, wherein the at least one Group IV element comprises lead.

8. The thermoelectric material of claim 1, wherein the at least one Group VI element comprises tellurium.

9. The thermoelectric material of claim 1, wherein the at least one Group IV element comprises lead, the at least one Group VI element comprises tellurium, and the at least one dopant comprises thallium with a dopant concentration in a range between about 0.5 atomic % and about 5 atomic %.

10. The thermoelectric material of claim 1, wherein the compound comprises a first atomic concentration of the at least one Group IV element and a second atomic concentration of the at least one Group VI element, the first atomic concentration less than the second atomic concentration.

11. The thermoelectric material of claim 1, wherein the at least one dopant further comprises at least one metal element.

12. The thermoelectric material of claim 11, wherein the at least one metal element comprises at least one alkali metal element selected from the group consisting of: lithium, sodium, potassium, rubidium, and cesium.

13. The thermoelectric material of claim 11, wherein the at least one metal element comprises at least one noble metal element selected from the group consisting of: silver, copper, gold.

14. The thermoelectric material of claim 1, wherein the at least one Group VI element comprises at least two elements selected from the group consisting of: tellurium, selenium, and sulphur.

15. The thermoelectric material of claim 14, wherein the compound comprises PbTe₁₋ₓSeₓ, with x between 0.01 and 0.99.

16. The thermoelectric material of claim 14, wherein the at least one Group IV element comprises lead and at least one element selected from the group consisting of: germanium and tin.

17. The thermoelectric material of claim 16, wherein the compound is selected from the group consisting of: Pb_{1-y}Sn_{y}SeₓTe₁₋ₓ, Pb_{1-y}Sn_{y}SₓTe₁₋ₓ, Pb_{1-y}Sn_{y}SₓSe₁₋ₓ, Pb_{1-y}Ge_{y}SeₓTe₁₋ₓ, Pb_{1-y}Ge_{y}SₓTe₁₋ₓ, and Pb_{1-y}Ge_{y}SₓSe₁₋ₓ, with 0.01<x<0.99 and 0.01<y<0.99.

18. The thermoelectric material of claim 1, wherein the at least one dopant comprises gallium, and an atomic concentration of the Group IV element is greater than an atomic concentration of the Group VI element by an amount in the range between about 0.1 atomic % to about 0.5 atomic %.

19. The thermoelectric material of claim 1, wherein the compound comprises an n-type thermoelectric material and the thermoelectric figure of merit ZT has a peak value greater than 1.1 at temperatures greater than 500 K.

20. The thermoelectric material of claim 1, wherein the compound comprises a p-type thermoelectric material.

21. The thermoelectric material of claim 1, wherein the at least one dopant comprises at least one first dopant and at least one second dopant.

22. The thermoelectric material of claim 21, wherein the first dopant comprises at least one element selected from the group consisting of indium, thallium, gallium, aluminum, and chromium, and the second dopant comprises at least one element selected from the group consisting of lithium, sodium, iodine, bromine, bismuth, antimony, and silver.

23. The thermoelectric material of claim 21, wherein the at least one Group IV element comprises lead, the at least one Group VI element comprises tellurium, the first dopant comprises at least one element selected from the group consisting of: gallium and aluminum, and the second dopant comprises at least one element selected from the group consisting of: a halogen, bismuth, and antimony.

24. The thermoelectric material of claim 23, wherein the second dopant comprises iodine or bromine.

25. The thermoelectric material of claim 21, wherein the first dopant comprises at least one element selected from the group consisting of indium, thallium, gallium, aluminum, and chromium and the second dopant comprises an excess amount of the Group VI element.

26. The thermoelectric material of claim 25, wherein the Group VI element is tellurium, selenium, or sulphur.

27. The thermoelectric material of claim 25, wherein an atomic concentration of the at least one Group VI element is greater than an atomic concentration of the at least one Group IV element, and the excess amount of the at least one Group VI element is equal to a difference between the atomic concentration of the at least one Group VI element and the atomic concentration of the at least one Group IV element.

28. The thermoelectric material of claim 21, wherein neither the first dopant nor the second dopant comprises thallium.

29. The thermoelectric material of claim 21, wherein neither the first dopant nor the second dopant comprises sodium.

30. A thermoelectric material comprising a doped Group IV-Group VI semiconductor compound, wherein the compound is doped with at least one dopant such that the compound has a density of electron states as a function of energy n(E) having an energy derivative dn(E)/dE with one or more maxima, and such that the Fermi level of the compound is located within kT of a maximum of the one or more maxima.

31. The thermoelectric material of claim 30, wherein the doped Group IV-Group VI semiconductor compound is a doped lead chalcogenide compound.

32. The thermoelectric material of claim 30, wherein the doped Group IV-Group VI semiconductor compound comprises at least one Group IV element selected from the group consisting of lead, tin, germanium, and silicon.

33. The thermoelectric material of claim 30, wherein the doped Group IV-Group VI semiconductor compound comprises at least one Group VI chalcogen selected from the group consisting of tellurium, selenium, sulfur, and oxygen.

34. The thermoelectric material of one of claims 1 or 30, wherein the doped compound is a nano-scale thermoelectric material.

35. The thermoelectric material of claim 34, wherein the nano-scale thermoelectric material comprises grains or particles having dimensions in a range between about 1 nanometer and about 100 nanometers.

36. A thermoelectric device comprising the thermoelectric material of one of claims 1 or 30.

37. A method of using the thermoelectric device of claim 36, wherein at least one portion of the thermoelectric device is exposed to a temperature greater than 300 K during operation of the thermoelectric device.

38. A method of fabricating a thermoelectric material, the method comprising:
providing at least one Group IV element, at least one Group VI element, and at least one dopant in predetermined stoichiometric amounts, wherein the at least one dopant is selected from the group consisting of: at least one Group IIa element, at least one Group IIb element, at least one Group IIIa element, at least one Group IIIb element, at least one lanthanide element, and chromium;
combining the at least one Group IV element, the at least one Group VI element, and the at least one dopant together; and
treating the combination of the at least one Group IV element, the at least one Group VI element, and the at least one dopant with a predetermined temporal temperature profile, wherein the combination of the at least one Group IV element, the at least one Group VI element, and the at least one dopant forms a compound with the at least one Group IV element on a first sublattice of sites and the at least one Group VI element is on a second sublattice of sites, wherein the at least one Group IV element comprises at least 95% of the first sublattice sites, wherein the compound has a peak thermoelectric figure of merit ZT value greater than 0.7 at temperatures greater than 500 K.
